(19) United States
(12) Patent Application Publication
(10) Pub. No.: US 2015/0103488 A1
(43) Pub. Date: Apr. 16, 2015

(54) CABLE SUPPORT APPARATUS AND INFORMATION PROCESSING APPARATUS

(71) Applicant: FUJITSU LIMITED, Kawasaki-shi (JP)

(72) Inventor: MASAYOSHI TANAKA, Kawasaki (JP)

(21) Appl. No.: 14/485,873

(22) Filed: Sep. 15, 2014

(30) Foreign Application Priority Data
Oct. 11, 2013 (JP) 2013-213902

(51) Int. Cl. H05K 7/14; F16L 3/12

(52) U.S. Cl. CPC H05K 7/1447; F16L 3/12
USPC 361/679.58; 248/68.1

(57) ABSTRACT

There is provided a cable support apparatus included in an information processing apparatus having a plurality of electronic equipment units, the cable support apparatus includes: a slide member configured to assemble cables connected to the plurality of electronic equipment units; a holding board on which the slide member is installed, the holding board being pivotable downward; and a link mechanism capable of sliding the slide member toward rotary shafts of the holding board, during the pivoting of the holding board.

### CROSS-REFERENCE TO RELATED APPLICATION

This application is based upon and claims the benefit of priority of the prior Japanese Patent Application No. 2013-213902, filed on Oct. 11, 2013, the entire contents of which are incorporated herein by reference.

### FIELD

The application discussed herein is related to a cable support apparatus and an information processing apparatus.

### BACKGROUND

Recently, an information processing apparatus such as a server includes, in a rack, a plurality of electronic equipment units that houses electronic circuits such as a hard disk device, memory, CPU, power supply unit, and so on. In each of the electronic equipment units installed in the rack, cables to be connected to the unit are held in the installation area of the unit and routed to the outside of the rack through cable storage space (cable forming area) on both sides of the back of the rack.

When the installation area for electronic equipment units is large enough (for example, electronic equipment units occupy about 50% of the unit installation area), a forming area for holding connection cables at all times is easily kept in the installation area for electronic equipment units. However, as the density of packaging becomes higher, the size of a rack is reduced and the number of units installed in the rack is increased. As a result, there is no room for the installation area for electronic equipment units in the rack and the electronic equipment units have occupied 80% to 90% of the size of the rack.

Since there is substantially no room for the cable storage space (forming area) for holding cables at all times in the rack, cable forming has been performed using pivotable cable supports or the like. Japanese Laid-open Patent Publication No. 10-215083 discloses an example of such a mechanism in which cable support bodies are disposed on supporting columns of a cabinet (rack) so as to project toward the back side of the cabinet and a cable support with a pivot angle of 90 degrees is attached to brackets disposed at the tip of the cable support bodies. Cables to be connected to a package installed in the cabinet are formed along the cable support and, during replacement of the package, the cable support is opened to keep space for inserting or removing the package.

### SUMMARY

According to an aspect of the invention, a cable support apparatus included in an information processing apparatus having a plurality of electronic equipment units, the cable support apparatus includes: a slide member configured to assemble cables connected to the plurality of electronic equipment units; a holding board on which the slide member is installed, the holding board being pivotable downward; and a link mechanism capable of sliding the slide member toward rotary shafts of the holding board, during the pivoting of the holding board.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a front view of an information processing apparatus;

FIG. 1B is a rear view of the information processing apparatus depicted in FIG. 1A;

FIG. 2A is a partially enlarged perspective view of a cable support apparatus on the back side of the information processing apparatus depicted in FIG. 1B;

FIG. 2B is a partially enlarged perspective view of a section of FIG. 2A;

FIG. 2C is a side view of the cable support apparatus depicted in FIG. 2A;

FIG. 3A is a partially enlarged view depicting a state in which the cable support apparatus in FIG. 2A has been opened;

FIG. 3B is a drawing corresponding to FIG. 2C when the cable support apparatus depicted in FIG. 2A is opened;

FIG. 4A is a side view of the cable support apparatus in FIG. 2C from which cables and connectors have been removed;

FIG. 4B is a side view of the cable support apparatus in FIG. 4A in which a cable support has been pulled out backward;

FIG. 4C is a side view of the cable support apparatus in FIG. 4B in which the cable support has been pivoted downward;

FIG. 5A is a sectional view of a standard cable used in the information processing apparatus depicted in FIG. 2A;

FIG. 5B is a sectional view of a cable having thick signal wires used in the information processing apparatus depicted in FIG. 2A;

FIG. 5C is a sectional view of a cable having many signal wires used in the information processing apparatus depicted in FIG. 2A;

FIG. 6 is an exploded perspective view depicting components constituting a cable support apparatus of an embodiment together with mount angles of the information processing apparatus;

FIG. 7A is a plan view of a slide board depicted in FIG. 6;

FIG. 7B is a front view of the slide board depicted in FIG. 6;

FIG. 7C is a plan view of a cable support depicted in FIG. 6;

FIG. 8 is an exploded view depicting a procedure for assembling the cable support apparatus in FIG. 6;

FIG. 9 is a perspective view of a part of the information processing apparatus into which the cable support apparatus has been built, seen from the back side;

FIG. 10A is a side view of the cable support apparatus depicted in FIG. 9;

FIG. 10B is a side view depicting a state in which the cable support of the cable support apparatus depicted in FIG. 10A has started pivoting relative to a relay board;

FIG. 10C is a side view depicting a state in which the cable support of the cable support apparatus in FIG. 10B has finished pivoting relative to the relay board;

FIG. 11A is a side view depicting a state in which an electronic equipment unit is pulled out from the back side of the information processing apparatus into which the cable support apparatus has been built;

FIG. 11B is a partially enlarged side view of the cable support apparatus depicted in FIG. 11A;

FIG. 11C is a side view depicting a state in which the cable support has been pivoted downward and the electronic equipment apparatus has been pulled out from the back side of the information processing apparatus in the information processing apparatus into which the cable support apparatus has been built;

FIG. 11D is a partially enlarged side view of the cable support apparatus depicted in FIG. 11A;

FIG. 12A is a side view depicting a state in which the cable support apparatus does not operate on the back side of the information processing apparatus to which the cable support apparatus has been built;

FIG. 12B is a side view depicting a state in which the cable support apparatus has been pivoted downward from the state depicted in FIG. 12A;

FIG. 13A is a partial perspective view of the information processing apparatus into which the cable support apparatus has been built, seen from the back side; and

FIG. 13B is a partial perspective view depicting a state in which the cable support apparatus is operating in the information processing apparatus depicted in FIG. 13A.

### DESCRIPTION OF EMBODIMENTS

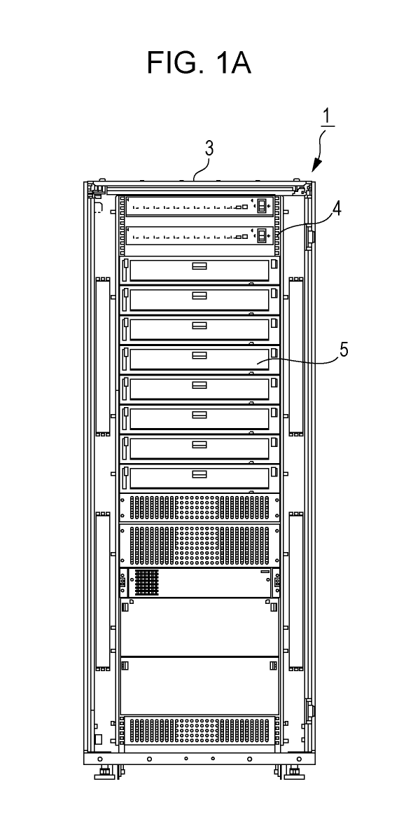

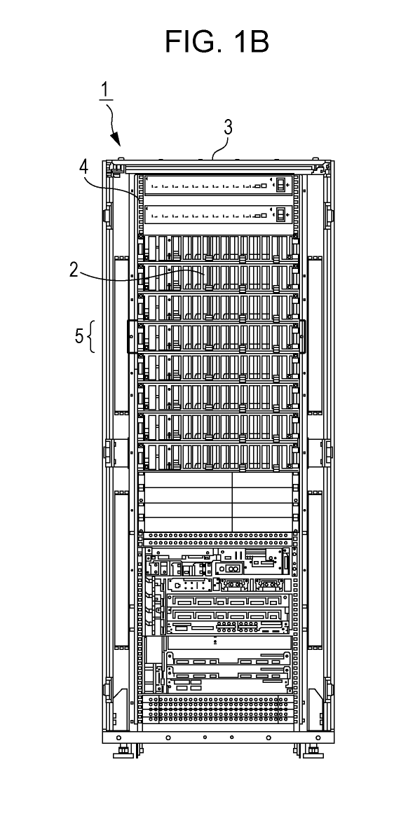

A cable support apparatus 90 will be described in detail with reference to FIGS. 1A to 5C. FIG. 1A is a front view depicting a whole information processing apparatus (rack mount type server) 1. FIG. 1B is a rear view of the information processing apparatus 1 depicted in FIG. 1A. Mount angles 4 are present at the four corners in a rack 3, which is the cabinet of the information processing apparatus 1. A plurality of steps of unit installation areas 5 are provided in the space enclosed by the mount angles 4. A plurality of electronic equipment units 2 may be installed in each of the unit installation areas 5. In the following description, the side on which the cables connected to the electronic equipment units 2 are present is assumed to be the back side or the rear.

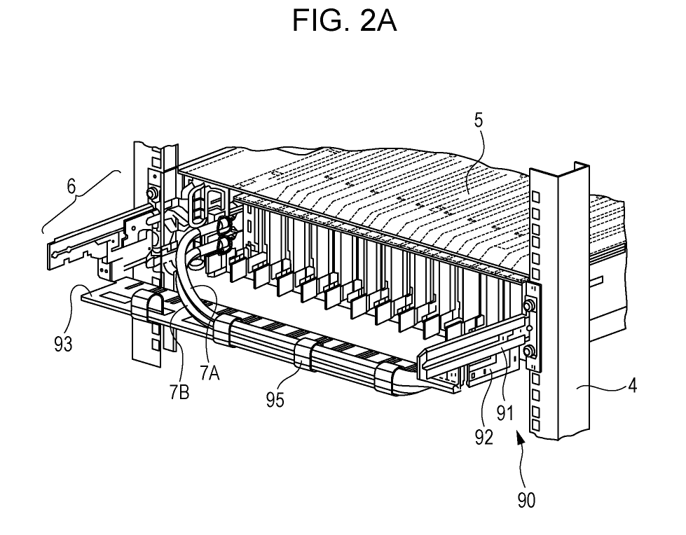

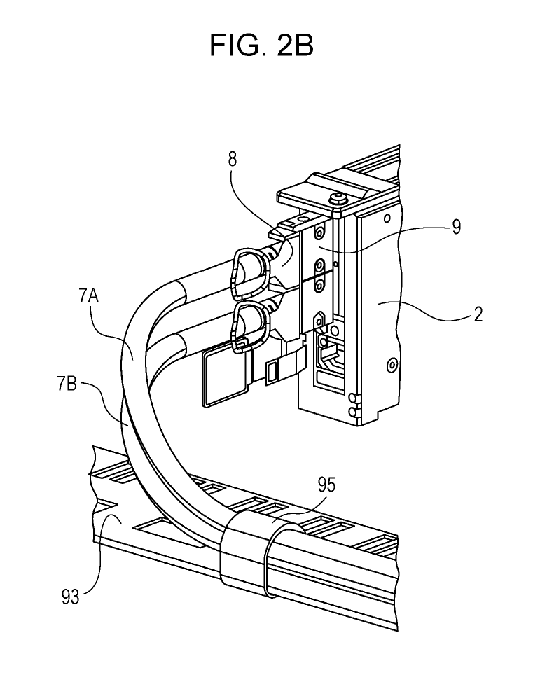

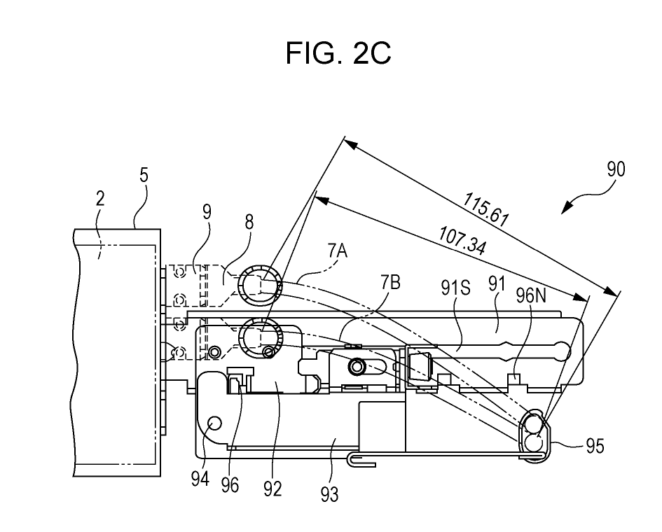

FIG. 2A is a partially enlarged view of one of the unit installation areas 5 on the back side of the information processing apparatus 1 depicted in FIG. 1B. A cable forming area 6 is present on the back side of the information processing apparatus 1 and the cable support apparatus 90 is present in the cable forming area 6. The cable support apparatus 90 holds, in the cable forming area 6, cables 7A and 7B for connecting the electronic equipment units 2 installed in the unit installation area 5 externally.

FIG. 2B is a partially enlarged view of the unit installation area 5 depicted in FIG. 2A. In FIG. 2A, the cables 7A and 7B to be connected to the electronic equipment unit 2 are depicted. Unit connectors 9 are disposed on the back side of the electronic equipment unit 2 and cable connectors 8 disposed at the ends of the cables 7A and 7B are connected to the unit connectors 9. On the back side of the electronic equipment unit 2, there are brackets 91 attached to the mount angles 4 in FIG. 2A and the cables 7A and 7B are held by a cable support 93 held by the brackets 91 via relay plates 92. Cable holding parts 95 fix the cables 7A and 7B to the cable support 93.

FIG. 2C is a side view of the cable support apparatus 90 depicted in FIG. 2B. FIG. 2C depicts a structure for attaching the cable support 93 to the brackets 91. The mount angles 4 to which the brackets 91 are attached are not depicted in this drawing. The bracket 91 is a metal plate extending backward from the mount angle 4 and has therein a slit 91S formed in a longitudinal direction. The relay plate 92 attached to the bracket 91 is movable along the slit 91S, but the relay plate 92 is normally fixed to the bracket 91 by a lock mechanism 96. The cable support 93 is attached pivotably around a rotary shaft 94 to the relay plate 92 attached to the bracket 91.

The cable connectors 8 for the cables 7A and 7B are connected to the unit connectors 9 of the electronic equipment unit 2 installed in the unit installation area 5 and the cables 7A and 7B are fixed by the cable holding parts 95 disposed on the cable support 93. The cable support 93 is arranged so as to be able to support the cables even when the height of the electronic equipment unit 2 has a different length such as 1U, 2U, 3U, 4U, . . . . Accordingly, the rotary shaft 94 of the cable support 93 is disposed in a lower part of the unit installation area 5.

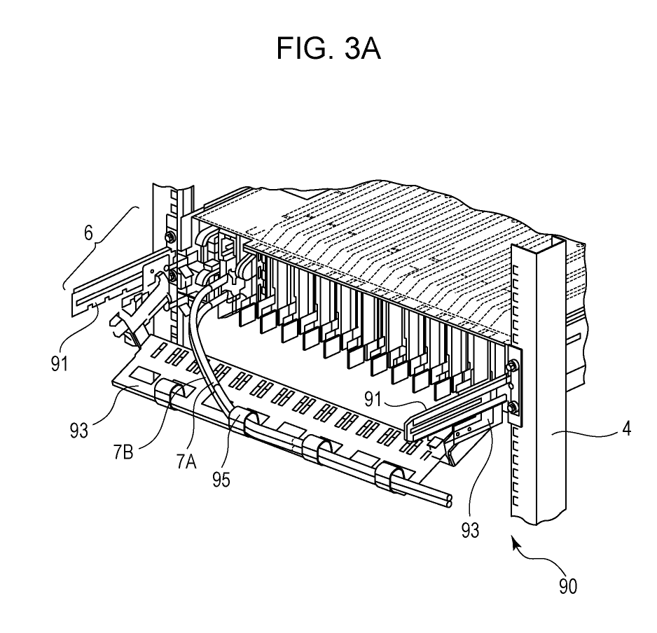

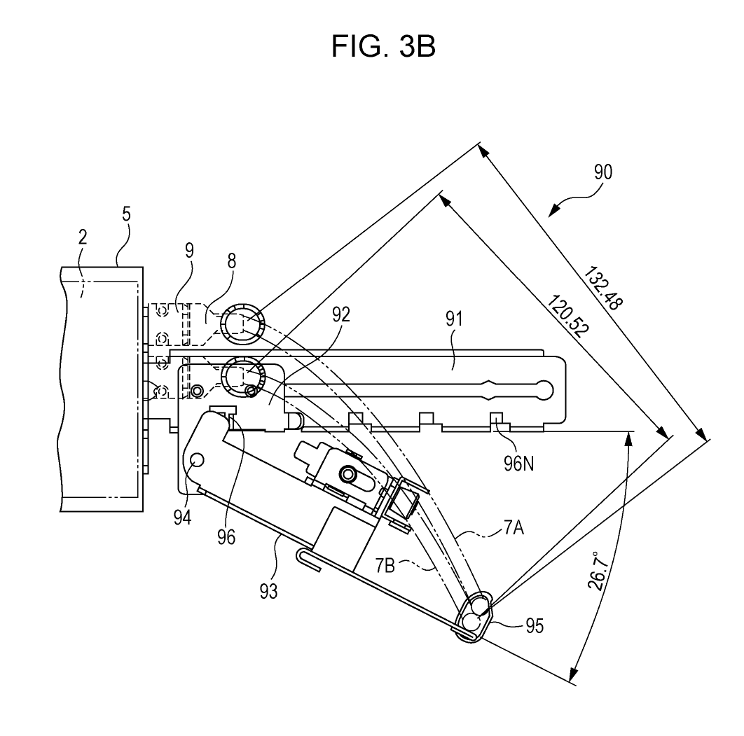

In the state depicted in FIG. 2C, the cables 7A and 7B interfere with a particular electronic equipment unit 2 installed in the unit installation area 5 when the electronic equipment unit 2 is removed from or attached to the unit installation area 5. Therefore, when any of the electronic equipment units 2 is removed from or inserted into the unit installation area 5, the cable support 93 is pivoted downward around the rotary shaft 94, as depicted in FIGS. 3A and 3B, to move the cables 7A and 7B from the insertion/removal path of the electronic equipment unit 2. At this time, if the cable support 93 is pivoted by 26.7 degrees from the position depicted in FIG. 2C, the cables 7A and 7B are moved from the insertion/removal path of the electronic equipment units 2.

If the cable support 93 is pivoted downward around the rotary shaft 94, the distance between the cable connector 8 and the cable holding part 95 increases as depicted in FIGS. 2C and 3B. Therefore, in the cable support apparatus 90, the cables 7A and 7B between the cable connector 8 and the cable holding part 95 are fixed with an extra length given, so that the length increased by pivoting of the cable support 93 is canceled.

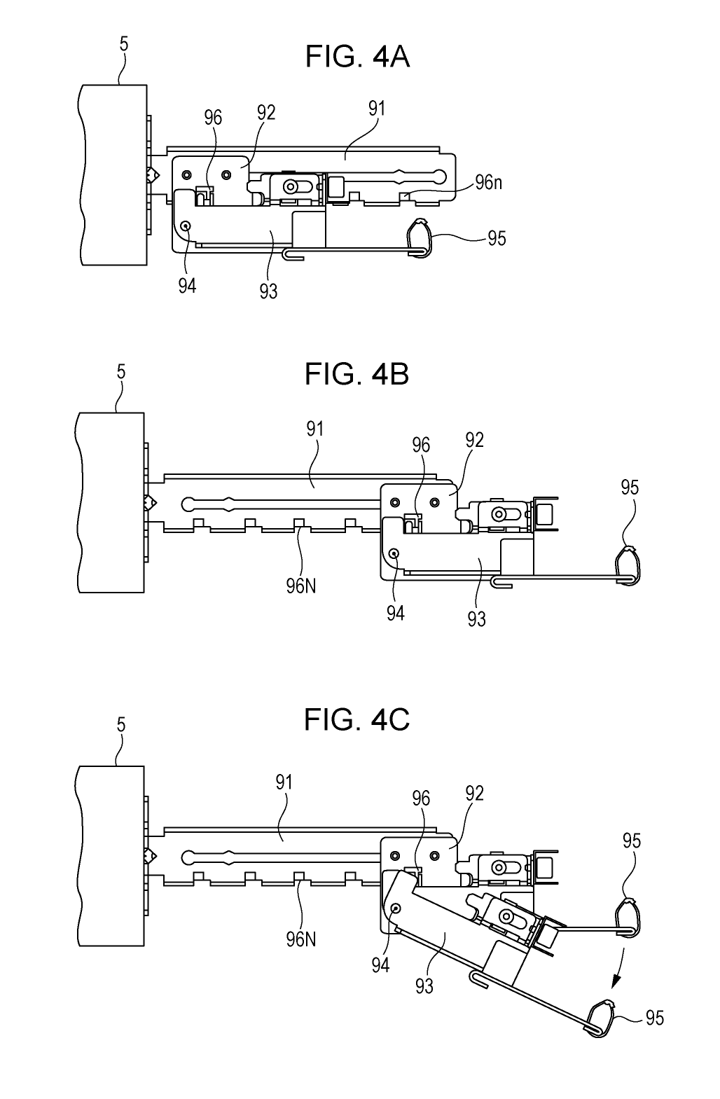

In the cable support apparatus 90, as depicted in FIGS. 4A to 4C, if engagement between the lock mechanism 96 and a lock groove 96N disposed in the bracket 91 is released, the relay plate 92 may be moved relative to the bracket 91. In FIGS. 4A to 4C, the cables 7A and 7B and the cable connector 8 and the unit connector 9 depicted in FIGS. 2C and 3B are not depicted. In the cable support apparatus 90, the moved relay plate 92 may be fixed by the lock mechanism 96 at the position of any of the lock grooves 96N. That is, the position of the cable support 93 may be changed between the position depicted in FIG. 4A and the position depicted in FIG. 4B by moving the relay plate 92. In addition, as depicted in FIG. 4C, the cable support 93 may be pivoted downward in the position in which the cable support 93 has been pulled out. As described above, when the length of the electronic equipment unit 2 installed in the unit installation area 5 is long and projects backward from the unit installation area 5, the position of the cable support 93 is desired to be changed.

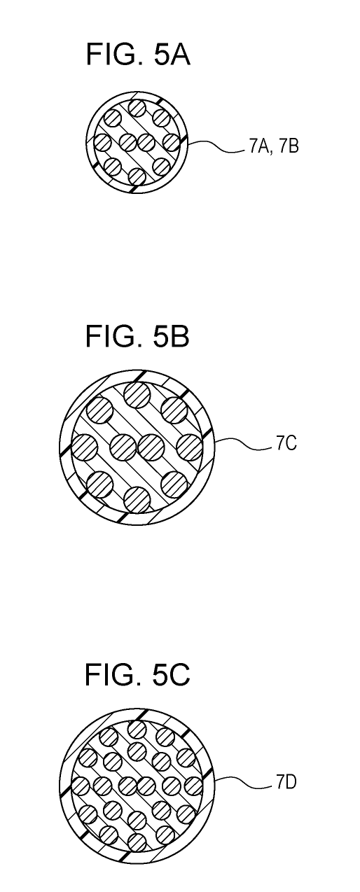

On the other hand, in recent years, the number of signals assigned to each connector is increasing as the density of packaging has become higher and the outer diameter of core wires in a cable is increasing as the transfer rate has increased, thereby increasing the outer diameter of the cable. Such a situation will be described with reference to FIGS. 5A to 5C. FIG. 5A is a sectional view of the standard cables 7A and 7B used in the information processing apparatus 1 depicted in FIG. 2A. The cables 7A and 7B, which were conventionally used, have a smaller diameter (for example, a diameter of less than 8 mm) and flexible. In contrast, the core wires of a cable 7C depicted in FIG. 5B have a larger diameter than conventional ones. The core wires of a cable 7D depicted in FIG. 5C have the same diameter of the core wires as conventional ones, but the diameter of the cable increases because the number of core wires increases.

If a cable becomes thicker and the minimum bending radius exceeds, for example, 40 mm, the cable bending radius may not be kept if an extra length is provided between the cable connection part (connector part) and the cable holding part in the cable support apparatus. Accordingly, if the cable is thicker, when the cable holding part is moved aside during insertion or removal of any of the electronic equipment units, the cable interferes with the pivoting of the cable support, possibly making it difficult to keep the unit insertion/removal area. In addition, if a thicker cable is routed with an extra length given, the cable connection part is loaded, possibly causing a cable break or a poor connection or possibly making it difficult to ensure reliability for a long time.

Embodiments of an information processing apparatus with a cable support apparatus capable of moving the cable support from the unit installation area (insertion/removal area) of electronic equipment regardless of the thickness and the minimum bending radius of a cable connected to an electronic equipment unit will be described below in detail based on specific examples.

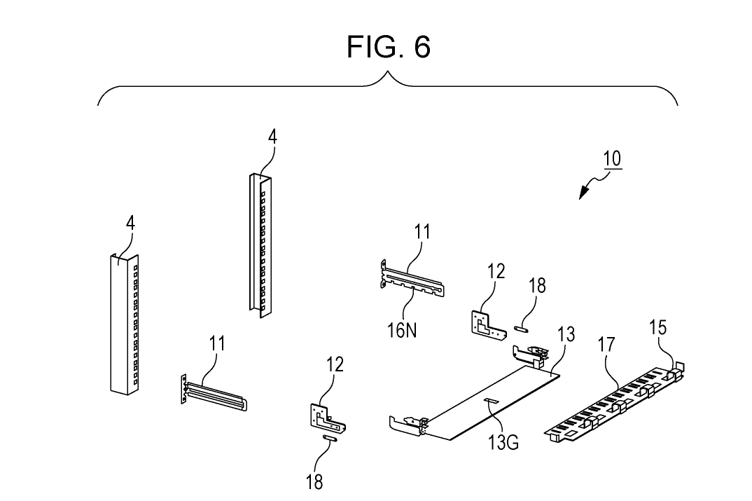

FIG. 6 depicts the components constituting a cable support apparatus 10 according to an embodiment together with mount angles 4, a part of the cabinet of an information processing apparatus (for example, a rack mount type server). The cable support apparatus 10 includes brackets 11, the relay board 12, a cable support 13 (an example of a holding board), a slide board 17, and links 18. The brackets 11 are fixed to the mount angles 4, respectively. Cable holding parts 15 are disposed on the slide board 17. The slide board 17 is placed on the cable support 13 so as to slide thereon. The cable support 13 is attached to the brackets 11 via the relay boards 12. The slide board 17 is linked to the relay boards 12 via the links 18. Assembling of these parts will be described later.

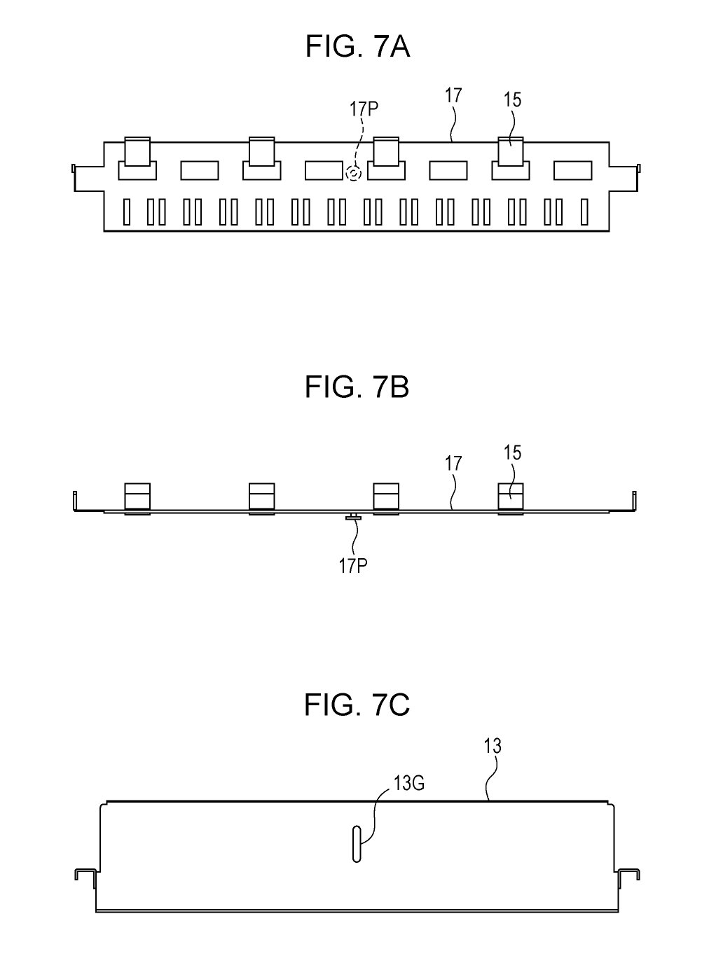

FIG. 7A is a plan view of the slide board 17 depicted in FIG. 6 and FIG. 7B is a front view of the slide board 17. FIG. 7C is a plan view of the cable support 13 depicted in FIG. 6. The plurality of cable holding parts 15 are disposed on an upper surface of the slide board 17 and a guide projection 17P is disposed on an undersurface. A guide groove 13G is disposed along a direction orthogonal to the longitudinal direction in the middle of the cable support 13. When the slide board 17 is placed on the cable support 13, the guide projection 17P disposed on the undersurface of the slide board 17 is inserted into the guide groove 13G. A detachable C-shaped ring (referred to below as the C-ring) is attached to the tip of the guide projection 17P. When the slide board 17 is placed on the cable support 13, the C-ring is detached and the guide projection 17P is inserted into the guide groove 13G. After the guide projection 17P in inserted, the C-ring may be attached to the guide projection 17P. The slide board 17 is formed so as to have substantially the same length in the longitudinal direction as the longitudinal direction of the cable support 13 so that the slide board is able to hold all cables connected to the electronic equipment units.

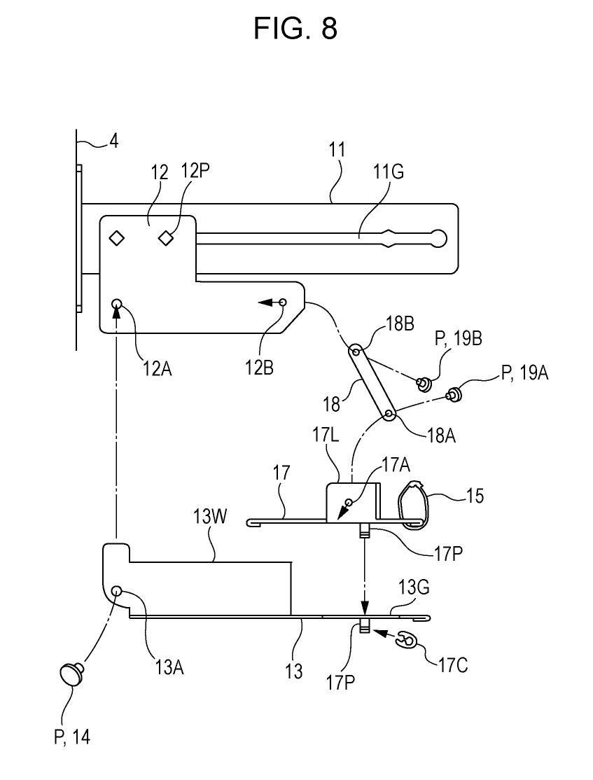

FIG. 8 depicts a procedure for assembling the cable support apparatus 10 in FIG. 6. When the cable support apparatus 10 is assembled, the brackets 11 are first attached by fixtures (not depicted) such as bolts to the two mount angles 4 on the back side of the information processing apparatus (not depicted), respectively. FIG. 8 depicts the procedure for attaching the bracket 11, the relay board 12, the slide board 17, and the link 18 to one of the two mount angles 4. Next, the relay board 12 is fixed to the bracket 11 with a fixture 12P according to the length of projection from the mount angle 4 at the rear end of the electronic equipment unit (not depicted) installed in the information processing apparatus. The fixture 12P is inserted into a slit 11G disposed in the bracket 11 and then tightened. The position of the relay board 12 depicted in FIG. 8 is determined assuming that the rear end of the electronic equipment unit (not depicted) installed in the information processing apparatus does not project backward beyond the mount angles 4.

Although the bracket 11 depicted in FIG. 6 has a lock groove (notch) 16N as in the bracket 91 described in FIGS. 4A to 4C, the bracket 11 depicted in FIG. 8 does not have a lock groove. Accordingly, the relay board 12 depicted in FIG. 8 may be moved along the slit 11G of the bracket 11 according to the length of projection from the mount angle 4 at the rear end of the electronic equipment unit installed in the information processing apparatus and may be fixed at an arbitrary position. When the lock groove 16N as depicted in FIG. 6 is disposed in the bracket 11 according to the present application, the relay board 12 may be moved along the slit 11G of the bracket 11 and may be fixed at the position of the lock groove 16N, as in the case described in FIGS. 4A to 4C.

On the other hand, in a process other than that for fixing the relay board 12 to the bracket 11, the slide board 17 is attached to the cable support 13. When the slide board 17 is attached to the cable support 13, the guide projection 17P projecting from the undersurface of the slide board 17 is inserted into the guide groove 13G of the cable support 13 and then the slide board 17 is placed on the cable support 13. Next, the C-ring 17C is attached to the tip of the guide projection 17P (indicated by a dotted line) projecting from the rear surface of the cable support 13 so that the guide projection 17P is not removed from the guide groove 13G. It is also possible to screw a screw with a head diameter larger than the width of a guide groove 13G into the tip of the guide projection 17P instead of attaching the C-ring 17C to keep the guide projection 17P from being removed from the guide groove 13G.

Side walls 13W are disposed on both sides of a portion of the cable support 13 closer to the mount angle 4. A shaft hole 13A is disposed in a portion of the side wall 13W closer to the mount angle 4. In addition, the cable holding parts 15 are provided on the upper surface of the slide board 17 and a linking piece 17L with a link hole 17A is disposed on each of both sides. The cable support 13 to which the slide board 17 has been attached is attached pivotably to the relay board 12 by aligning the shaft hole 13A with a shaft hole 12A of the relay board 12 and inserting a pin P to form a rotary shaft 14. Finally, the link 18 having linking holes 18A and 18B at both ends is installed between the relay board 12 and the slide board 17 with the coupling hole 18A aligned with the coupling hole 17A, the pin P is inserted into the holes, the coupling hole 18B is aligned with a link hole 12B, and then the pin P is inserted into the holes. The rotary shafts formed by inserting the pins P at both ends of the link 18 are assumed to be rotary shafts 19A and 19B.

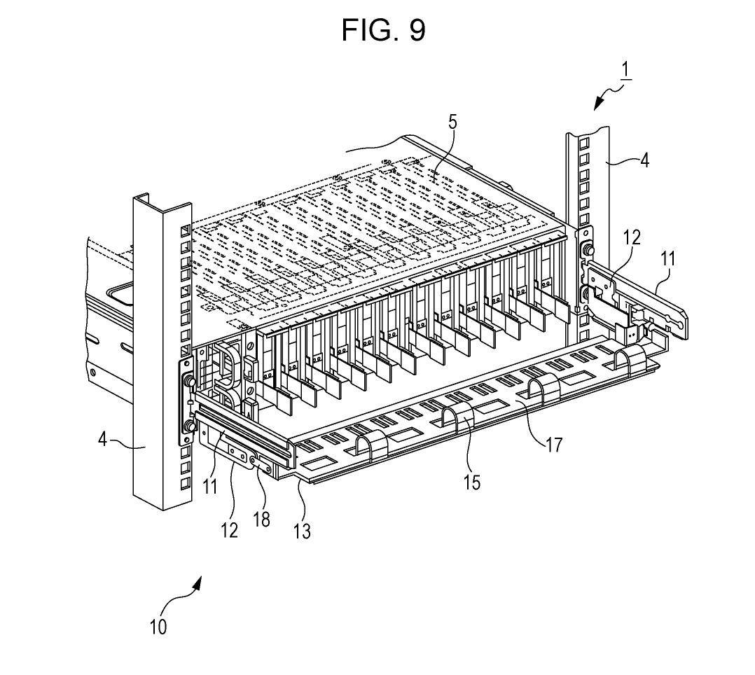

FIG. 9 depicts a part of the information processing apparatus 1 into which the cable support apparatus 10 according to the present application has been built, seen from the back side. The information processing apparatus 1 has a plurality of steps of unit installation areas 5 each having a plurality of electronic equipment units and the cable support apparatus 10 is disposed at the back side of each step of the unit installation area 5. No cables are attached yet to the cable support apparatus 10 depicted in FIG. 9.

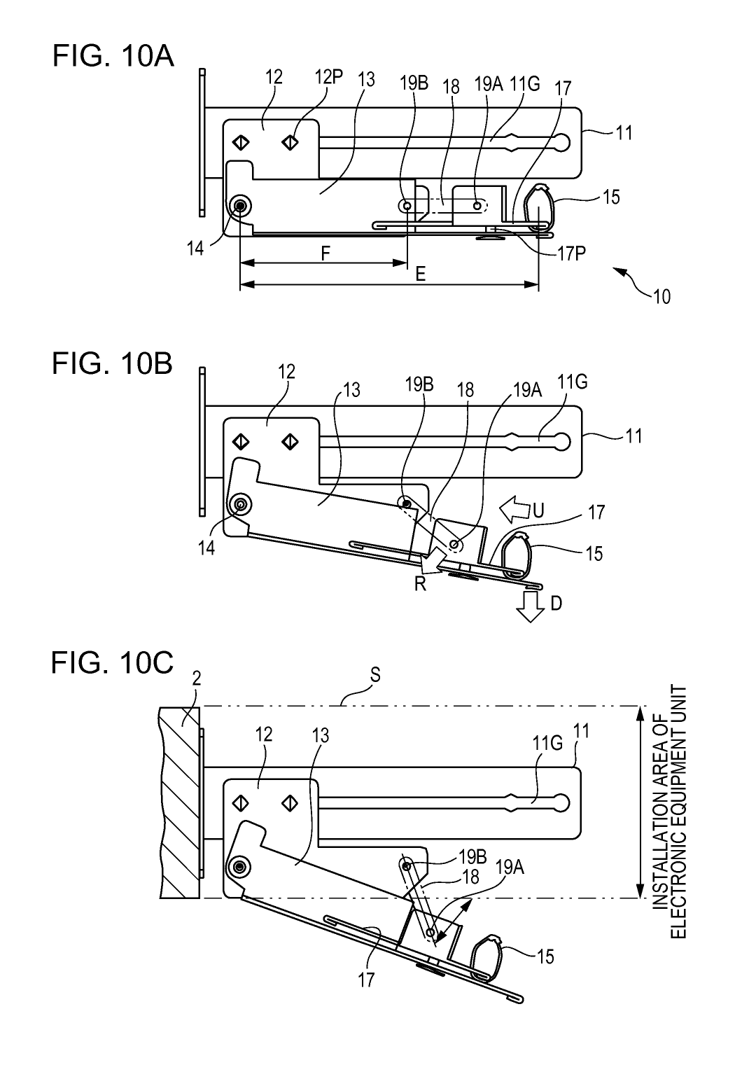

The operation of the cable support apparatus 10 attached to the mount angles 4 of the information processing apparatus 1 will be described with reference to FIGS. 10A to 10C. FIG. 10A is a side view of the cable support apparatus 10 depicted in FIG. 9. The distance F between the rotary shaft 14 of the cable support 13 disposed on the relay board 12 and the rotary shaft 19B of the link 18 does not change. In contrast, the distance E between the rotary shaft 14 and the cable holding part 15 disposed on the slide board 17 changes when the cable support 13 is pivoted.

FIG. 10B depicts a state in which the cable support 13 of the cable support apparatus 10 depicted in FIG. 10A has started pivoting in the direction of arrow D relative to the relay board 12 around the rotary shaft 14. When the cable support 13 is pivoted around the rotary shaft 14 in the direction of arrow D, the link 18, which is connected to the slide board 17 via the rotary shaft 19A, is pivoted around the rotary shaft 19B in the direction of arrow R. Since the length of the link 18 does not change, the slide board 17, which is connected to the link 18 via the rotary shaft 19A, slides on the cable support 13 in the direction of arrow U. Accordingly, the cable holding part 15 on the slide board 17 moves toward the rotary shaft 14.

FIG. 10C is a side view depicting a state in which the cable support 13 of the cable support apparatus 10 in FIG. 10B has finished pivoting relative to the relay board 12. In this state, the slide board 17 connected to the link 18 via the rotary shaft 19A slides on the cable support 13 and moves downward as the cable holding part 15 on the slide board 17 moves toward the rotary shaft 14. In FIG. 10C, the rear end of an electronic equipment unit 2 installed in the information processing apparatus 1 and the installation area (insertion/removal area) S of the electronic equipment unit 2 are indicated by dash-dot-dot lines. When the cable support 13 has finished pivoting relative to the relay board 12, the cable holding part 15 on the slide board 17 is located below the installation area S of the electronic equipment unit 2. Accordingly, the cable holding part 15 does not interfere with the movement of the electronic equipment unit 2 during replacement of the electronic equipment unit 2.

The distance by which the slide board 17 slides on the cable support 13 may be adjusted by the length of the link 18. If the length of the link 18 is increased, the movement distance of the cable holding part 15 is reduced. If the length of the link 18 is reduced, the movement distance of the cable holding part 15 is increased. In addition, if a plurality of shaft holes are disposed in the relay board 12 and the link 18 and a shaft hole of the relay board 12 is combined with a shaft hole of the link 18 to adjust the length of the link 18, the movement distance of the cable holding part 15 is changed, thereby enabling flexible adjustment.

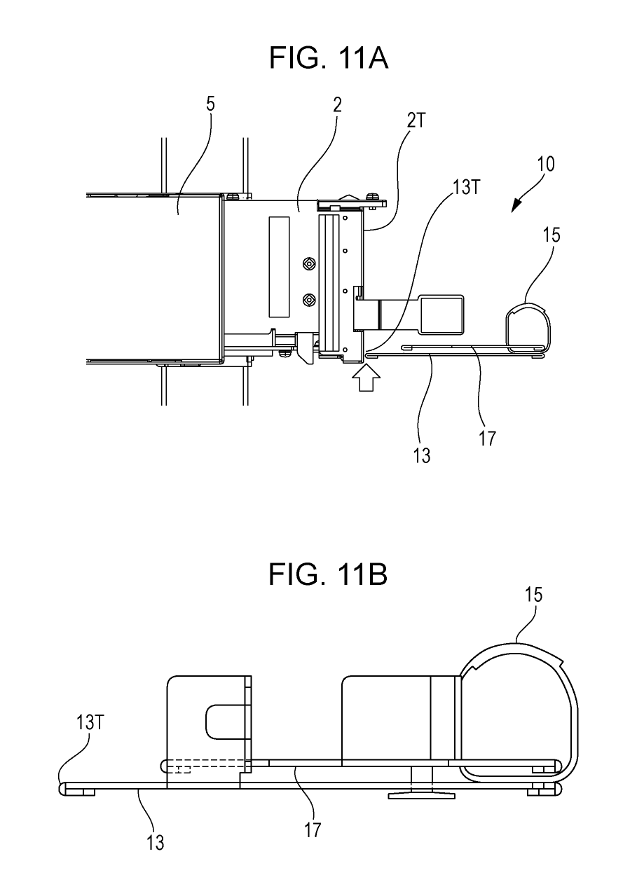

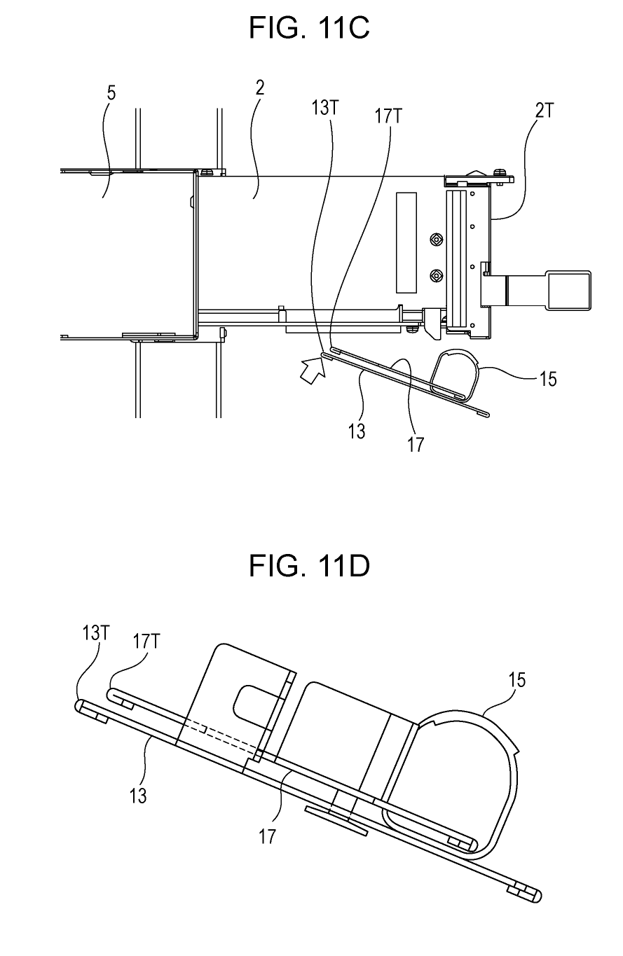

FIG. 11A depicts a state in which one of the electronic equipment units 2 is pulled out from the unit installation area 5 in a normal state in which the cable support 13 is not pivoted on the back side of the information processing apparatus 1 into which the cable support apparatus 10 according to the present application has been built. FIG. 11B is a partially enlarged view of the cable support apparatus 10 depicted in FIG. 11A. Since an end 2T of the electronic equipment units 2 makes contact with an end 13T of the cable support 13 as depicted by the arrow in a normal state in which the cable support 13 is not pivoted, it is impossible to pull out the electronic equipment unit 2 from the back side of the information processing apparatus 1.

FIG. 11C is a side view depicting a state in which the cable support 13 has been pivoted downward in the information processing apparatus 1 into which the cable support apparatus 10 according to the present application has been built. FIG. 11D is a partially enlarged side view of the cable support apparatus 10 depicted in FIG. 11C. In a state in which the cable support 13 is pivoted, the slide board 17 moves on the cable support 13 as depicted in FIG. 11D, so an end 17T of the slide board 17 is close to the end 13T of the cable support 13. In this state, as depicted in FIG. 11C, when the electronic equipment unit 2 is pulled out from the unit installation area 5, the end 17T of the slide board 17, the end 13T of the cable support 13, and the cable holding part 15 are all located below the end 2T of the electronic equipment units 2. Accordingly, it is possible to pull out the electronic equipment unit 2 from the back side of the information processing apparatus 1 and to insert the electronic equipment unit 2 into the unit installation area 5 of the information processing apparatus 1 from the back side.

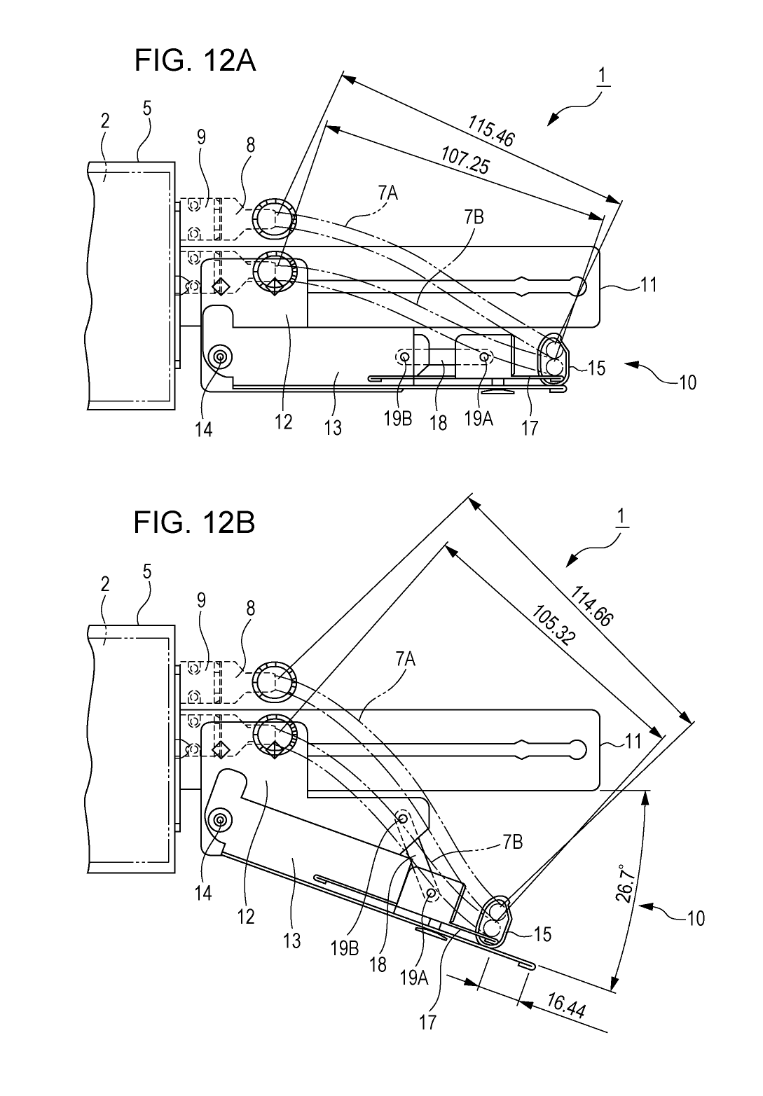

FIG. 12A depicts a state in which the cable support apparatus 10 does not operate on the back side of the information processing apparatus 1 to which the cable support apparatus 10 according to the present application has been built. The cables 7A and 7B connected, via the cable connectors 8, to the unit connectors 9 of the electronic equipment unit 2 installed in the information processing apparatus 1 are fixed to the cable holding part 15 disposed on the slide board 17. FIG. 12B depicts a state in which the cable support 13 of the cable support apparatus 10 has been pivoted downward from the state depicted in FIG. 12A.

In the cable support apparatus 90 depicted in FIGS. 2C and 3B, if the cable support 93 is pivoted downward, the distance between the cable connector 8 and the cable holding part 95 increases. Accordingly, in the cable support apparatus 90 depicted in FIGS. 2C and 3B, the cables 7A and 7B between the cable connectors 8 and the cable holding part 95 are fixed with an extra length given, so that the length increased by pivoting of the cable support 93 is canceled. However, the diameter of the cable is larger, it is impossible to provide an extra length for the cables 7A and 7B between the cable connectors 8 and the cable holding part 95, so the cable support apparatus 90 depicted in FIGS. 2C and 3B is unavailable for thicker cables.

In contrast, even if the cable support 13 is pivoted downward in the cable support apparatus 10 depicted in FIGS. 12A and 12B, there is little variation in the distance between the cable connector 8 and the cable holding part 15 because of movement of the link 18 and the slide board 17. Accordingly, in the cable support apparatus 10, there is no desire to provide an extra length for the cables 7A and 7B between the cable connector 8 and the cable holding part 95. Consequently, the cable support apparatus 10 is applicable even when it is difficult to provide an extra length for the cables 7A and 7B between the cable connector 8 and the cable holding part 95 because the cables 7A and 7B are thick and hard. In addition, a pivoting angle of the cable support 13 desired to insert or remove the electronic equipment unit does not change between the cable support apparatus 10 and the cable support apparatus 90 depicted in FIGS. 2C and 3B.

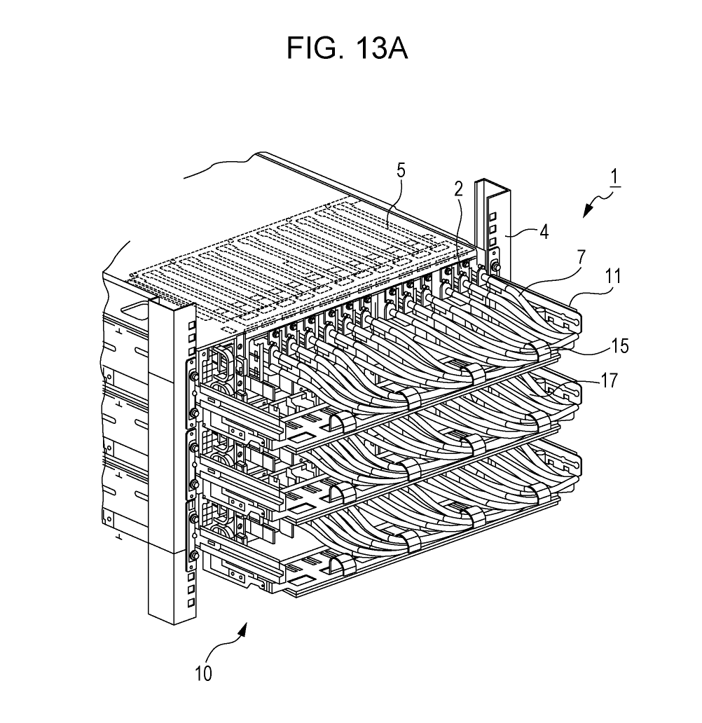

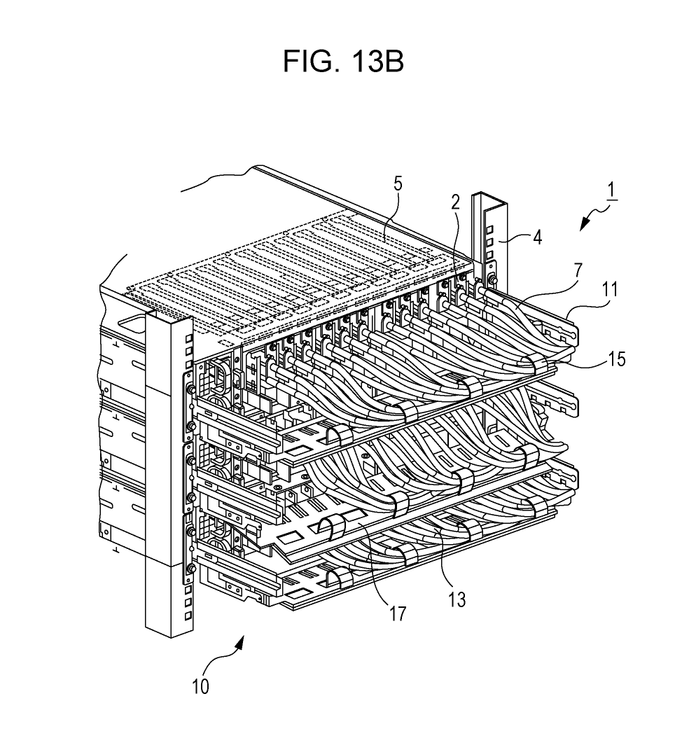

FIG. 13A is a rear view of the information processing apparatus 1 according to an embodiment into which the cable support apparatus 10 has been built. There are three steps of unit installation areas 5 in FIG. 13A. As many cables 7 (cables 7A and 7B) as electronic equipment units 2 installed in the unit installation area 5 are connected to the back side of the unit installation area 5 for each step and are fixed to the cable holding part 15 on the slide board 17 of the cable support apparatus 10. The cable support apparatus 10 holds the cables 7 connected to the back side of the information processing apparatus 1 so that the cables 7 do not invade the areas of other units.

For example, when an electronic equipment unit 2 on the second step of three steps of unit installation areas 5 depicted in FIG. 13A is inserted or removed, only the cable support 13 of the cable support apparatus 10 on the second step is pivoted downward, as depicted in FIG. 13B. The cable support 13 of the cable support apparatus 10 on the second step may be pivoted downward regardless of the states of the cable support apparatuses 10 on the first and third steps. The unit insertion/removal area is kept by pivoting the cable support 13 downward to move the cables 7 and the cable holding part 15 aside.

As described above, the cable support apparatus and the information processing apparatus having a cable support apparatus are able to keep the unit insertion/removal area of an electronic equipment unit regardless of the thickness and minimum bending radius of a cable connected to the electronic equipment unit. As a result, during replacement of the electronic equipment unit, active replacement is achieved while the information processing apparatus operates, thereby improving the efficiency of maintenance of the information processing apparatus.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A cable support apparatus included in an information processing apparatus having a plurality of electronic equipment units, the cable support apparatus comprising:
a slide member configured to assemble cables connected to the plurality of electronic equipment units;
a holding board on which the slide member is installed, the holding board being pivotable downward; and
a link mechanism capable of sliding the slide member toward rotary shafts of the holding board, during the pivoting of the holding board.

2. The cable support apparatus according to claim 1, wherein
the holding board is attached, via the rotary shafts, to relay boards attached to brackets fixed to a cabinet of the information processing apparatus, and
the link mechanism includes links that link the relay boards to the slide member, and pins via which both ends of the links are linked to the relay boards and the slide member, respectively.

3. The cable support apparatus according to claim 2, wherein
the brackets are two brackets parallel to each other,
the holding board is a plate-like member having a length large enough to assemble cables from all of the electronic equipment units to be pulled out between the two brackets, the holding board being linked by the rotary shafts to
the relay boards via side walls of the holding board, respectively, and one ends of the links are linked to the relay boards at positions distant from the rotary shafts of the relay boards.

4. The cable support apparatus according to claim 3, wherein
the holding board includes at least one guide groove extending in a longitudinal direction of the brackets, and
the slide member includes a guide projection slidable in the guide groove, on an undersurface of the slide member.

5. The cable support apparatus according to claim 4, wherein
when the holding board is pivoted downward at a maximum around the rotary shafts and the slide member is slid by using the links toward the rotary shafts, a pivoting angle of the holding board and a length of the links are determined so that cables assembled by the holding board are located below installation areas of the electronic equipment units.

6. The cable support apparatus according to claim 5, wherein
the brackets includes slits provided in a longitudinal direction of the brackets,
the relay boards are attached to the brackets by fixtures that pass through the slits, and
the relay boards are slidable along the slits when the fixtures are loosened so as to change positions in the brackets in which the relay boards are installed to positions more distant from the cabinet of the information processing apparatus.

7. An information processing apparatus having a cable support apparatus that, when one of a plurality of electronic equipment units to be installed in a cabinet of an information processing apparatus is inserted into the cabinet or removed from the cabinet, moves cables connected to the other electronic equipment units from an insertion/removal area of the plurality of electronic equipment units, the cable support apparatus comprising:
a slide member configured to assemble the cables connected to the plurality of electronic equipment units;
a holding board on which the slide member is installed, the holding board being pivotable downward; and
a link mechanism capable of sliding the slide member toward rotary shafts of the holding board, during the pivoting of the holding board.

8. The information processing apparatus according to claim 7, wherein
the holding board is attached, via the rotary shafts, to relay boards attached to brackets fixed to a cabinet of the information processing apparatus, and
the link mechanism includes links that link the relay boards to the slide member, and pins via which both ends of the links are linked to the relay boards and the slide member, respectively.

9. The information processing apparatus according to claim 8, wherein
the brackets are two brackets parallel to each other,
the holding board is a plate-like member having a length large enough to assemble cables from all of the electronic equipment units to be pulled out between the two brackets, the holding board being linked by the rotary shafts to the relay boards via side walls of the holding board, respectively, and
one ends of the links are linked to the relay boards at positions distant from the rotary shafts of the relay boards.

10. The information processing apparatus according to claim 9, wherein
the holding board includes at least one guide groove extending in a longitudinal direction of the brackets, and
the slide member includes a guide projection slidable in the guide groove, on an undersurface of the slide member.

11. The information processing apparatus according to claim 10, wherein
when the holding board is pivoted downward at a maximum around the rotary shafts and the slide member is slid by the links towards the rotary shafts, a pivoting angle of the holding board and a length of the links are determined so that cables assembled by the holding board are located below installation areas of the electronic equipment units.

12. The information processing apparatus according to claim 11, wherein
the brackets includes slits are provided in a longitudinal direction of the brackets,
the relay boards are attached to the brackets by fixtures that pass through the slits, and
the relay boards are slidable along the slits when the fixtures are loosened so as to change positions in the brackets in which the relay boards are installed to positions more distant from the cabinet of the information processing apparatus.
